(19) United States
(12) Patent Application Publication
(10) Pub. No.: US 2017/0005285 A1
(43) Pub. Date: Jan. 5, 2017

(54) ORGANIC LIGHT-EMITTING DEVICE AND METHOD FOR MANUFACTURING THE SAME, AND DISPLAY APPARATUS

(71) Applicants: BOE TECHNOLOGY GROUP CO., LTD., Beijing (CN); ORDOS YUANSHENG OPTOELECTRONICS CO., LTD., Ordos (CN)

(72) Inventors: Jiandong BAO, Beijing (CN); Minhui JIA, Beijing (CN); Jin XU, Beijing (CN); Peng CAO, Beijing (CN)

(21) Appl. No.: 15/067,670

(22) Filed: Mar. 11, 2016

(30) Foreign Application Priority Data
Jun. 30, 2015 (CN) 201510374892.6

(51) Int. Cl. H01L 51/50; H01L 51/00; H01L 51/52; H01L 51/56

(52) U.S. Cl. CPC H01L 51/5088; H01L 51/56; H01L 51/001; H01L 51/5221; H01L 51/5072; H01L 51/5096; H01L 51/5092; H01L 51/5012; H01L 51/5056; H01L 51/5206

(57) ABSTRACT

Disclosed is an organic light-emitting device, including: a first electrode, a second electrode and an organic functional layer provided between the first electrode and the second electrode, wherein the organic functional layer includes: a hole injection layer, a hole transport layer, and an insulating layer formed in at least one of the hole injection layer and the hole transport layer. A method for manufacturing the above organic light-emitting device is also disclosed. A display apparatus including the above organic light-emitting device is disclosed.

### TECHNICAL FIELD

Embodiments of the present disclosure relate to an organic light-emitting device and a method for manufacturing the same, and a display apparatus.

### BACKGROUND

An organic light-emitting diode (referred to as OLED) display is a self-luminous display. The light-emitting mechanism of OLED is that under the influence of the applied electric field, electrons and holes are injected respectively from positive and negative poles to an organic light-emitting material, thereby performing migration, recombination and attenuation in the organic light-emitting material to be luminous.

### SUMMARY

Embodiments of the present disclosure provide an organic light-emitting device and a method for manufacturing the same, and a display apparatus. By adding an insulating layer, the injection and transport of holes are effectively reduced, thereby balancing the transport of carriers and improving the luminous efficiency and life of OLED devices.

In a first aspect, embodiments of the present disclosure provide an organic light-emitting device, comprising: a first electrode, a second electrode, and an organic functional layer provided between the first electrode and the second electrode, the organic functional layer comprising: a hole injection layer, a hole transport layer, an organic light-emitting layer, and an insulating layer formed in at least one of the hole injection layer and the hole transport layer.

In some embodiments, the hole transport layer is disposed between the hole injection layer and the organic light-emitting layer. In some embodiments, the hole transport layer and the hole injection layer are disposed adjacent to each other.

In some embodiments, the organic functional layer further comprises: at least one selected from the group consisting of an electron transport layer, an electron injection layer and a hole blocking layer.

In some embodiments, the insulating layer is prepared by a first process.

In some embodiments, both the hole injection layer and the hole transport layer are prepared by a second process.

In some embodiments, the first process comprises chemical vapor deposition.

In some embodiments, the second process comprises vacuum thermal evaporation.

In a second aspect, embodiments of the present disclosure provide a method for manufacturing an organic light-emitting device, comprising: forming a first electrode, an organic functional layer and a second electrode sequentially on a substrate, forming the organic functional layer comprising: forming a hole injection layer, forming a hole transport layer, forming an organic light-emitting layer, and forming an insulating layer, the insulating layer being located in at least one of the hole injection layer and the hole transport layer.

In some embodiments, forming the organic functional layer further comprises: forming an electron transport layer.

In some embodiments, forming the insulating layer comprises: preparing an insulating material layer by a first process and etching the insulating material layer to form the insulating layer.

In some embodiments, forming the organic functional layer comprises: preparing the hole injection layer by a second process and preparing the hole transport layer by the second process.

In some embodiments, the first process comprises chemical vapor deposition.

In some embodiments, the second process comprises vacuum thermal evaporation.

In a third aspect, the present disclosure provides a display apparatus, comprising the above organic light-emitting device.

As can be seen from the aforementioned technical solutions, the present disclosure provides an organic light-emitting device and a method of manufacturing the same, and a display apparatus. By adding an insulating layer to at least one of the hole injection layer and the hole transport layer, the hole injection amount can be effectively reduced and the hole transport speed can be slowed down, such that carriers can be more effectively recombined in a light-emitting layer and the luminous efficiency and life of OLED devices are improved. Meanwhile, by adding an insulating layer, less vapor deposition materials will be used.

### BRIEF DESCRIPTION OF THE DRAWINGS

In order to illustrate the technical solutions of the embodiments of the present disclosure more clearly, the drawings of the embodiments are simply described below. Apparently, the drawings described below relate to only some embodiments of the present disclosure and are not limitative of the present disclosure.

FIG. 1 is a schematic structural view of an OLED device.

FIG. 2 is a schematic structural view of an organic light-emitting device according to an embodiment of the present disclosure.

FIG. 3 is a flow diagram of a method of manufacturing an organic light-emitting device according to another embodiment of the present disclosure.

### DETAILED DESCRIPTION

To make clearer the objects, technical solutions and advantages of the embodiments of the present disclosure, a clear and full description of the technical solutions of the embodiments of the present disclosure will be made with reference to the accompanying drawings of the embodiments of the present disclosure. Obviously, the embodiments described are merely part of rather than all of the embodiments of the present disclosure. Based on the embodiments of the present disclosure described, all the other embodiments acquired by a person of ordinary skill in the art, without any creative labor, fall within the scope of protection of the present disclosure.

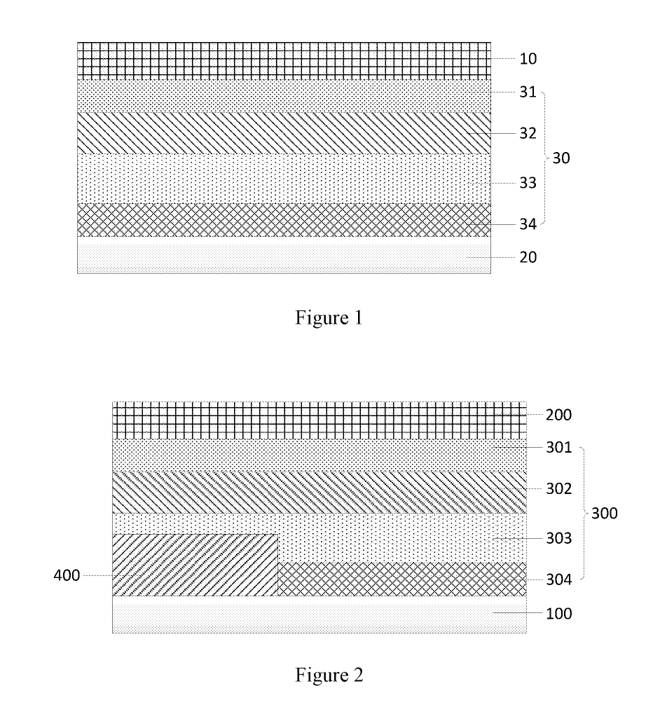

An OLED device structure is as shown in FIG. 1, including a cathode layer 10, an anode layer 20, and an organic functional layer 30 located between the cathode layer 10 and the anode layer 20. The organic functional layer 30 comprises an electron transport layer 31, an organic light-emitting layer 32, a hole transport layer 33 and a hole injection layer 34. In the light-emitting process of OLED, the mobility of the hole transport layer is greater than that of the electron transport layer, which leads a large number of holes to gather in the organic light-emitting material near the side of the electron transport layer, resulting in transmission disequilibrium of carriers such as holes and electrons, greatly reducing the luminous efficiency.

However, in order to make carriers such as holes and electrons to maintain a balance in the transmission process, there are methods of increasing the hole transport layer or adding a blocking layer. But this increases the amount of the material used, and the effect is not ideal.

FIG. 2 is a schematic structural view of an organic light-emitting device according to an embodiment of the present disclosure. The organic light-emitting device comprises: a first electrode 100, a second electrode 200 and an organic function layer 300 provided between the first electrode 100 and the second electrode 200.

The organic functional layer 300 comprises: a hole injection layer 304, a hole transport layer 303, an organic light-emitting layer 302, and an insulating layer 400 formed in at least one of the hole injection layer 304 and the hole transport layer 303.

As shown in FIG. 2, in some embodiments, the insulating layer 400 is formed on the first electrode 100, and at the same time located in the hole injection layer 304 and the hole transport layer 303. As such, part of the insulating layer formed in the hole injection layer 304 can reduce the injection amount of the hole while part of the insulating layer formed in the hole transport layer 303 can slow down the transport speed of the hole, thereby finally causing the hole and the electron to be effectively recombined in an organic light-emitting layer 302 so as to emit light.

It shall be noted that except for the structure as shown in FIG. 2 of the present embodiment, the thickness and location of the insulating layer can be changed, which is not limited in the present embodiment. For instance, the insulating layer can be located in either the hole injection layer or the hole transport layer, or can be simultaneously located in both of the hole injection layer and the hole transport layer, and the thickness of the insulating layer is less than or equal to the sum of the thicknesses of the hole injection layer and the hole transport layer. By changing the thickness and location of the insulating layer, the hole injection amount and the hole transport speed are controlled, thereby balancing the transport of carriers such as holes and electrons, which then can be effectively recombined in an organic light-emitting layer to be luminous, thus improving the luminous efficiency. Therefore, in some embodiments, the projected area of the insulating layer on the first electrode is less than the projected area of the hole transport layer and the hole injection layer on the first electrode. In some embodiments, the thickness of the insulating layer is less than the sum of the thickness of the hole transport layer and the thickness of the hole injection layer. In the present application, the expression “the insulating layer is located in at least one of the hole injection layer and the hole transport layer” means that the thickness of the insulating layer is less than the sum of the thickness of the hole injection layer and the thickness of the hole transport layer, and the projection of the insulating layer on the first electrode is located within the projection of the hole transport layer and the hole injection layer on the first electrode.

In the present embodiment, as shown in FIG. 2, the organic functional layer 300 further comprises an electron transport layer 301. It shall be noted that the structure of the organic functional layer is not limited thereto. The organic functional layer may comprise at least one selected from the group consisting of an electron transport layer, an electron injection layer and a hole blocking layer.

In the present embodiment, the insulating layer 400 is prepared by a first process. The organic functional layers such as the hole injection layer 304 and the hole transport layer 303 are both prepared by a second process.

It shall be noted that the first process and the second process may be selected from any of the current substrate manufacturing processes capable of achieving patterning. In the present embodiment, the first process comprises chemical vapor deposition and the second process comprises vacuum thermal evaporation.

The present embodiment provides an organic light-emitting device. By adding an insulating layer to at least one of the hole injection layer and the hole transport layer, the hole injection amount can be effectively reduced and the hole transport speed can be slowed down, such that carriers can be more effectively recombined in a light-emitting layer and the luminous efficiency and life of OLED devices are improved. Meanwhile, by adding an insulating layer, less vapor deposition materials will be used.

Another embodiment of the present disclosure provides a method of manufacturing an organic light-emitting device, the method comprising: forming a first electrode, an organic functional layer and a second electrode sequentially on a substrate. Specifically, forming the organic functional layer comprises: forming a hole injection layer, forming a hole transport layer, forming an organic light-emitting layer, and forming an insulating layer, wherein the insulating layer is located in at least one of the hole injection layer and the hole transport layer.

In the present embodiment, forming the organic functional layer further comprises the step of forming an electron transport layer.

Specifically, forming the insulating layer comprises: preparing an insulating material layer by a first process and etching the insulating material layer to form the insulating layer.

Specifically, forming the organic functional layer comprises: preparing the hole injection layer by a second process and preparing the hole transport layer by the second process.

In the present embodiment, the first process comprises chemical vapor deposition and the second process comprises vacuum thermal evaporation. In some embodiments, the first process is carried out prior to the second process.

A further embodiment of the present disclosure provides a display apparatus comprising the above organic light-emitting device. The display device can be a product or component having display functions such as a display, a TV set, a mobile phone, a navigator, a digital photo frame, a video camera, a camera or the like.

### EXAMPLE 1

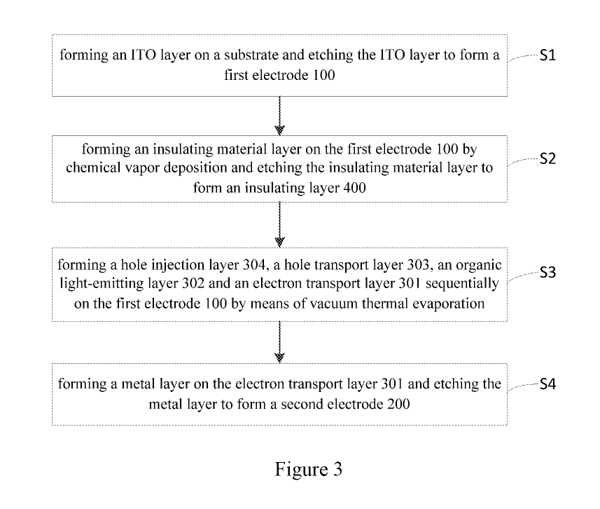

In order to illustrate the technical solution of the present disclosure more clearly, a specific example, i.e., Example 1, of the present disclosure will be illustrated in light of the cross-sectional schematic view of the device structures formed in various steps. In the example, the product structure is as shown in FIG. 2. It shall be understood that the structure illustrated herein is exemplary, and there may be other structural forms in accordance with the scope and spirit defined by the claims of the present disclosure. As shown in FIG. 3, the manufacturing method of the example may specifically comprise the steps of S1, S2, S3, and S4.

S1: forming an indium tin oxide (ITO) layer on a substrate and etching the ITO layer to form a first electrode 100, wherein the substrate may be transparent glass.

S2. forming an insulating material layer on the first electrode layer 100 by chemical vapor deposition and etching the insulating material layer to form an insulating layer 400.

S3. forming a hole injection layer 304, a hole transport layer 303, an organic light-emitting layer 302 and an electron transport layer 301 sequentially on the insulating layer 400 and the first electrode 100 by means of vacuum thermal evaporation; wherein the insulating material may be silicon oxide, silicon nitride or the like. The thickness and location of the insulating layer 400 can be changed. The insulating layer 400 can be located in at least one of the hole injection layer 304 and the hole transport layer 303, while the thickness of the insulating layer 400 is less than or equal to the sum of the thicknesses of the hole injection layer 304 and the thicknesses of the hole transport layer 303. As shown in FIG. 2, the insulating layer 400 is located in the hole injection layer 304 and the hole transport layer 303, which can effectively reduce the size of the hole injection layer 304 and the hole transport layer 303, reduce the amount of vapor depositions materials used, and reduce the hole injection amount and the hole transport speed. Moreover, all layers other than the insulating layer 400 in the organic functional layer can be formed by means of vacuum vapor deposition, which can effectively reduce process steps.

S4: forming a metal layer on the electron transport layer 301 and etching the metal layer to form a second electrode 200, wherein the metal layer can be an Al (aluminum) layer or an alloy MgAg.

The above are merely exemplary embodiments of the present disclosure, and are not intended to limit the scope of protection of the present disclosure, which is yet determined by the appended claims.

The present application claims the priority of the Chinese patent application No. 201510374892.6 submitted on Jun. 30, 2015, and the content disclosed in the above Chinese patent application is incorporated herein by reference as part of the present application.

What is claimed is:

1. An organic light-emitting device, comprising: a first electrode, a second electrode, and an organic functional layer provided between the first electrode and the second electrode, wherein:
the organic functional layer comprises: a hole injection layer, a hole transport layer, an organic light-emitting layer, and an insulating layer located in at least one of the hole injection layer and the hole transport layer.

2. The organic light-emitting device according to claim 1, wherein the organic functional layer further comprises at least one selected from the group consisting of an electron transport layer, an electron injection layer or a hole blocking layer.

3. The organic light-emitting device according to claim 1, wherein the insulating layer is prepared by a first process.

4. The organic light-emitting device according to claim 1, wherein the hole injection layer and the hole transport layer are both prepared by a second process.

5. The organic light-emitting device according to claim 3, wherein the first process comprises chemical vapor deposition.

6. The organic light-emitting device according to claim 4, wherein the second process comprises vacuum thermal evaporation.

7. The organic light-emitting device according to claim 1, wherein a projected area of the insulating layer on the first electrode is less than a projected area of the hole transport layer and the hole injection layer on the first electrode.

8. The organic light-emitting device according to claim 1, wherein a thickness of the insulating layer is less than a sum of a thickness of the hole transport layer and a thickness of the hole injection layer.

9. The organic light-emitting device according to claim 1, wherein the hole transport layer is disposed between the hole injection layer and the organic light-emitting layer.

10. The organic light-emitting device according to claim 1, wherein the hole transport layer and the hole injection layer are disposed adjacent to each other.

11. A method for manufacturing an organic light-emitting device, comprising: forming a first electrode, an organic functional layer and a second electrode sequentially on a substrate, wherein:
forming the organic functional layer comprises: forming a hole injection layer, forming a hole transport layer, forming an organic light-emitting layer, and forming an insulating layer, and the insulating layer is located in at least one of the hole injection layer and the hole transport layer.

12. The method according to claim 11, wherein forming the organic functional layer further comprises:
forming an electron transport layer.

13. The method according to claim 11, wherein forming the insulating layer comprises:
preparing an insulating material layer by a first process and etching the insulating material layer to form the insulating layer.

14. The method according to claim 11, wherein forming the organic functional layer comprises:
preparing the hole injection layer by a second process and preparing the hole transport layer by the second process.

15. The method according to claim 13, wherein the first process comprises chemical vapor deposition.

16. The method according to claim 14, wherein the second process comprises vacuum thermal evaporation.

17. A display apparatus, comprising the organic light-emitting device according to claim 1.

18. The display apparatus according to claim 17, wherein the organic functional layer further comprises at least one selected from the group consisting of an electron transport layer, an electron injection layer or a hole blocking layer.

19. The display apparatus according to claim 17, wherein a projected area of the insulating layer on the first electrode is less than a projected area of the hole transport layer and the hole injection layer on the first electrode.

20. The display apparatus according to claim 17, wherein a thickness of the insulating layer is less than a sum of a thickness of the hole transport layer and a thickness of the hole injection layer.
